(19) United States
(12) Patent Application Publication
(10) Pub. No.: US 2011/0150237 A1
(43) Pub. Date: Jun. 23, 2011

(54) Signal processing device and signal processing method

(75) Inventors: Makoto Nagasue, Tokyo (JP); Naotaka Saito, Tokyo (JP)

(73) Assignee: OKI SEMICONDUCTOR CO., LTD., Tokyo (JP)

(21) Appl. No.: 12/926,947

(22) Filed: Dec. 20, 2010

(30) Foreign Application Priority Data
Dec. 21, 2009 (JP) 2009-289120

(51) Int. Cl. H04B 15/00; H03G 3/00; H03F 99/00

(52) U.S. Cl. 381/94.1; 381/107; 381/120

(57) ABSTRACT

A signal processing device includes a non-inverting amplifier, an inverting amplifier, a converter, and a controller. The non-inverting amplifier amplifies a level of an analog sound signal input from outside with a first gain whose value is variable. The inverting amplifier amplifies a level of the analog sound signal amplified by the non-inverting amplifier with a second gain whose value is variable. The converter converts the analog sound signal amplified by the inverting amplifier to a digital sound signal. The controller detects a level of the digital sound signal converted by the converter and, in accordance with the detected level of the digital sound signal converted by the converter, controls the first gain and the second gain such that a level of the analog sound signal input to the converter is at a pre-specified level.

### CROSS-REFERENCE TO RELATED APPLICATION

This application claims priority under 35 USC 119 from Japanese Patent Application No. 2009-289120 filed on Dec. 21, 2009, the disclosure of which is incorporated by reference herein.

### BACKGROUND OF THE INVENTION

1. Field of the Invention

The present invention relates to a signal processing device and a signal processing method that automatically adjust levels of input signals.

2. Related Art

On a microphone recording channel of sound to be recorded by a digital video camera, a digital still camera, a digital voice recorder or the like, a device (hereinafter, a signal processing device) is provided for converting an input analog sound signal to a digital signal and amplifying the level thereof.

For example, in Japanese Patent Application Laid-Open (JP-A) No. 2009-273045, a signal processing device is disclosed that is provided with a programmable gain amplifier (PGA), which amplifies an input sound signal with a gain whose magnitude is variable, an analog-to-digital converter (ADC), which converts the analog sound signal amplified by the PGA to a digital sound signal, and an auto level controller (ALC), which controls the magnitude of the gain of the PGA. Although not shown in the drawings in JP-A No. 2009-273045, it is common for a microphone amplifier that amplifies the analog sound signal with a gain of a fixed magnitude to be provided preceding the PGA.

FIG. 10 is a diagram illustrating an example of a circuit diagram of a related art signal processing device. An input analog sound signal passes through a microphone amplifier 111 and is amplified. The analog sound signal amplified by the microphone amplifier 111 is amplified by a PGA 112. The analog sound signal amplified by the PGA 112 is input to an ADC 114. In the example illustrated in FIG. 10, in order to counteract earthing noise, a differential input-type converter is used as the ADC 114, another amplifier 113 is provided succeeding the PGA 112, and a differential signal is generated by the PGA 112 and the amplifier 113. The ADC 114 generates a digital sound signal from the differential signal generated by each of the PGA 112 and the amplifier 113, and inputs the digital sound signal to an ALC 115. A single input-type ADC may be employed and the amplifier 113 not provided. The ALC 115 detects a level of the input digital sound signal (the amplitude or magnitude of the sound), and controls the magnitude of the gain of the PGA 112 in accordance with the detected level. A decimation filter and a DC-cut high pass filter (HPF) or the like that perform thinning processing and suchlike may be provided succeeding the ADC 114 and preceding the ALC 115.

Ordinarily, the structure of a non-inverting amplifier in which an input impedance does not change is used for the microphone amplifier 111. This is because, if the structure of an inverting amplifier in which the input impedance changes is used, the input impedance varies along with effects on the output of the connected microphone. Further, the related art microphone amplifier 111 includes a gain (for example, around 30 dB max.) that is not controlled by the ALC 115. That is, the gain of the microphone amplifier 111 does not vary dynamically but is used as a fixed gain. Specification of the gain of the microphone amplifier 111 may be changed by a user before use in accordance with characteristics of the microphone to be attached and the environment of use. In FIG. 10, a resistor (resistance) R is divided in two, with one side being used as a feedback resistor and the other side being used as a resistor that is connected to the feedback resistor. The resistor R is a pre-set resistor, and the division ratio is specified beforehand by a user.

Thus, in the above-described conventional signal processing device, amplification at the analog side is performed by the microphone amplifier 111 with fixed gain and the PGA 112 with variable gain. However, with this structure, in order to change the level of the analog sound signal smoothly, it is necessary to widen the range of the PGA 112 (the range over which the gain can be varied) and realize the gain with a large number of steps (resolution) for when the gain is changed step by step. Therefore, it is necessary to use quite a large resistor as the resistor provided at the PGA 112. If a large resistor is mounted in an LSI, noise (thermal noise) is produced in accordance with the size of the resistor, which leads to a deterioration in the signal to noise ratio (SNR). That is, the recording performance (SNR) deteriorates.

### SUMMARY

The present invention is proposed in consideration of the above, and provides a signal processing device and a signal processing method capable of amplifying an analog sound signal to a required level while restraining noise and circuit size.

One aspect of the present invention is a signal processing device including: a non-inverting amplifier that amplifies a level of an analog sound signal input from outside with a first gain whose value is variable; an inverting amplifier that amplifies a level of the analog sound signal amplified by the non-inverting amplifier with a second gain whose value is variable; a converter that converts the analog sound signal amplified by the inverting amplifier to a digital sound signal; and a controller that detects a level of the digital sound signal converted by the converter and, in accordance with the detected level of the digital sound signal converted by the converter, controls the first gain and the second gain such that a level of the analog sound signal input to the converter is at a pre-specified level.

Thus, because of this structure in which the first gain of the non-inverting amplification section and the second gain of the inverting amplification section are variable, a resistor value that is required for amplification of the analog sound signal may be smaller than in a configuration in which the first gain is fixed and only the second gain is variable. Therefore, an analog sound signal may be amplified to a required level while thermal noise is moderated and circuit size is restrained.

The aspect described above may further include a zero-crossing detector that detects zero-crossing points of the analog sound signal amplified by the inverting amplifier; wherein the controller controls the first gain and the second gain when a zero-crossing point is detected by the zero-crossing detector.

The aspect described above may further include a first high pass filter connected to a non-inverting input terminal of the non-inverting amplifier; and a second high pass filter connected to an inverting input terminal of the non-inverting amplifier, wherein a cut-off frequency of the first high pass filter is higher than a cut-off frequency of the second high pass filter.

In order to moderate popcorn noise, it is common to control gain by detecting zero-crossing points. In related art, because the gain of a non-inverting amplification section is fixed, detecting zero-crossing points and varying the gain of the non-inverting amplification section has not been done. If a non-inverting amplification section is configured with the gain being variable and is switched (varied) at zero-crossing points, a phase delay arises in the analog sound signal because of the second high pass filter formed at the non-inverting amplification section, and popcorn noise may become significant. However, with a structure as described above such that the cut-off frequency of the first high pass filter is higher than the cut-off frequency of the second high pass filter, a signal component that produces a phase delay in response to the second high pass filter may be cut off, and therefore noise that is caused by the phase delay may be moderated.

Another aspect of the present invention is a signal processing device including: a non-inverting amplification circuit that amplifies an input analog sound signal with a first gain whose value is variable, the non-inverting amplification circuit including a first operational amplifier, a first capacitor, one end of which is connected to a non-inverting input terminal of the first operational amplifier, the analog sound signal being input through the other end of the first capacitor and the first capacitor removing a DC component of the analog sound signal, a first resistor, one end of which is connected to the non-inverting input terminal of the first operational amplifier, a reference voltage being applied to the other end of the first resistor, a second resistor, one end of which is connected to an output terminal of the first operational amplifier and the other end of which is connected to an inverting input terminal of the first operational amplifier, the second resistor functioning as a feedback resistor, a second capacitor, one end of which is grounded, the second capacitor being for removing an offset voltage of the first operational amplifier, and a third resistor, one end of which is connected to the other end of the second capacitor and the other end of which is connected to the inverting input terminal of the first operational amplifier; an inverting amplification circuit that amplifies the analog sound signal amplified by the non-inverting amplification circuit with a second gain whose value is variable, the inverting amplification circuit including a second operational amplifier, the reference voltage being applied to a non-inverting input terminal thereof, a fourth resistor, one end of which is connected to an output terminal of the second operational amplifier and the other end of which is connected to an inverting input terminal of the second operational amplifier, the fourth resistor functioning as a feedback resistor, and a fifth resistor, one end of which is connected to the output terminal of the first operational amplifier and the other end of which is connected to the inverting input terminal of the second operational amplifier; a conversion circuit that converts the analog sound signal amplified by the inverting amplification circuit to a digital sound signal; and a control circuit that detects a level of the digital sound signal converted by the conversion circuit and, in accordance with the detected level of the digital sound signal converted by the conversion circuit, controls the first gain and the second gain such that a level of the analog sound signal input to the conversion circuit is at a pre-specified level.

Thus, because of this structure in which the first gain of the non-inverting amplification section and the second gain of the inverting amplification section are variable, a resistance value that is required for amplification of the analog sound signal may be smaller than in a configuration in which the first gain is fixed and only the second gain is variable. Therefore, an analog sound signal may be amplified to a required level while thermal noise is moderated and circuit size is restrained.

The aspect described above may further include: a comparator that is connected to the control circuit and that compares the analog sound signal amplified by the inverting amplification circuit with the reference voltage and detects zero-crossing points, wherein the control circuit controls the first gain and the second gain when a zero-crossing point is detected by the comparator, and a cut-off frequency of a first high pass filter that is formed by the first capacitor and the first resistor is higher than a cut-off frequency of a second high pass filter that is formed by the second capacitor and the third resistor.

According to the structure described above, because a component that produces a phase delay in response to the second high pass filter may be cut off, noise caused by the phase delay may be moderated.

Yet another aspect of the present invention is a signal processing method including: primarily amplifying a level of an analog sound signal input from outside, with a first gain whose value is variable; secondarily amplifying a level of the analog sound signal which has been primarily amplified, with a second gain whose value is variable; converting the analog sound signal which has been secondarily amplified to a digital sound signal; detecting a level of the converted digital sound signal; and, in accordance with the detected level of the converted digital sound signal, controlling the first gain and the second gain such that a level of the analog sound signal to be converted is at a pre-specified level.

According to this method, similarly to the first aspect, a resistance value that is required for amplification of the analog sound signal may be smaller than in a configuration in which the first gain is fixed and only the second gain is variable, and an analog sound signal may be amplified to a required level while thermal noise is moderated and circuit size is restrained.

The aspect described above may further include controlling the first gain and the second gain when a zero-crossing point of the secondarily amplified analog sound signal is detected.

The aspect described above may further include providing a first high pass filter connected to a non-inverting input terminal of a non-inverting amplifier which performs the primary amplifying and a second high pass filter connected to an inverting input terminal of the non-inverting amplifier, and setting a cut-off frequency of the first high pass filter higher than a cut-off frequency of the second high pass filter.

According to this method, because a component that produces a phase delay in response to the second high pass filter may be cut off, noise caused by the phase delay may be moderated.

According to the present aspects described above, an effect is provided in that an analog sound signal may be amplified to a required level while noise and circuit size are restrained.

### BRIEF DESCRIPTION OF THE DRAWINGS

An exemplary embodiment of the present invention will be described in detail based on the following figures, wherein:

FIG. 1 is a diagram illustrating a structural example of a signal processing device of an exemplary embodiment;

FIG. 2 is a diagram illustrating an example of a circuit diagram of the signal processing device relating to the exemplary embodiment;

FIG. 3 is a table illustrating an example of assignment of gains when the magnitude of the gain of a PGA is variable and the magnitude of the gain of a microphone amplifier is fixed (in a structure of a related art technology), and an example of assignment of gains when the magnitudes of the gains of both of a PGA and a microphone amplifier are variable;

FIG. 4 is a diagram illustrating a structural example of a signal processing device provided with a zero-crossing detector;

FIG. 5 is a diagram illustrating an example of a circuit diagram corresponding to FIG. 4;

FIG. 6 is a diagram describing zero-crossing points;

FIG. 7 is a diagram illustrating an example of popcorn noise when gain is switched;

FIG. 8A and FIG. 8B are explanatory diagrams describing the relationship between an input analog sound signal and cut-off frequencies fc1 and fc2;

FIG. 9 is a table illustrating simulation results of examples of settings of the cut-off frequencies fc1 and fc2 and noise amounts; and

FIG. 10 is a diagram illustrating a circuit structure example of a related art signal processing device.

### DETAILED DESCRIPTION

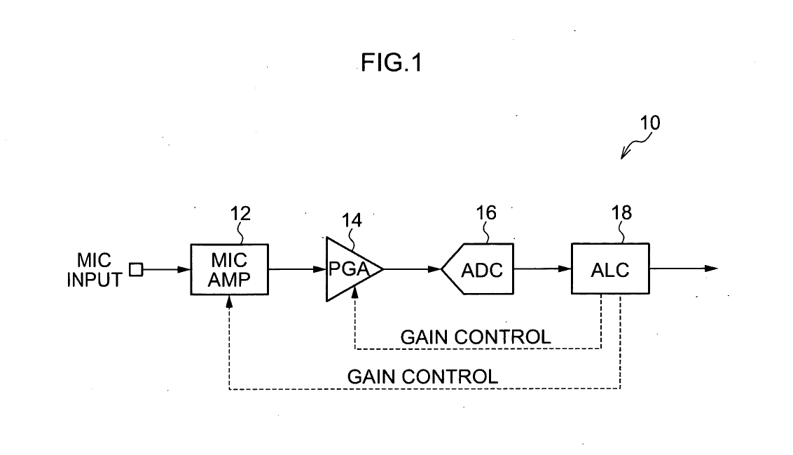

FIG. 1 is a diagram illustrating a structural example of a signal processing device 10 of the present exemplary embodiment. The signal processing device 10 of the present exemplary embodiment is provided on a recording channel that records input sound, and includes a microphone amplifier 12, a programmable gain amplifier (PGA) 14, an analog-to-digital converter (ADC) 16 and an auto level controller (ALC) 18.

An analog sound signal that is input via an unillustrated microphone is input to the microphone amplifier 12 and amplified. The analog sound signal amplified by the microphone amplifier 12 is amplified by the PGA 14. The analog sound signal amplified by the PGA 14 is converted to a digital sound signal by the ADC 16 and input to the succeeding ALC 18. The ALC 18 detects a level of the input digital sound signal and, depending on the detected level, controls the magnitudes of the respective gains of the microphone amplifier 12 and the PGA 14 such that the analog sound signal input to the ADC 16 is at a pre-specified level. Next, the structural elements are described in more detail.

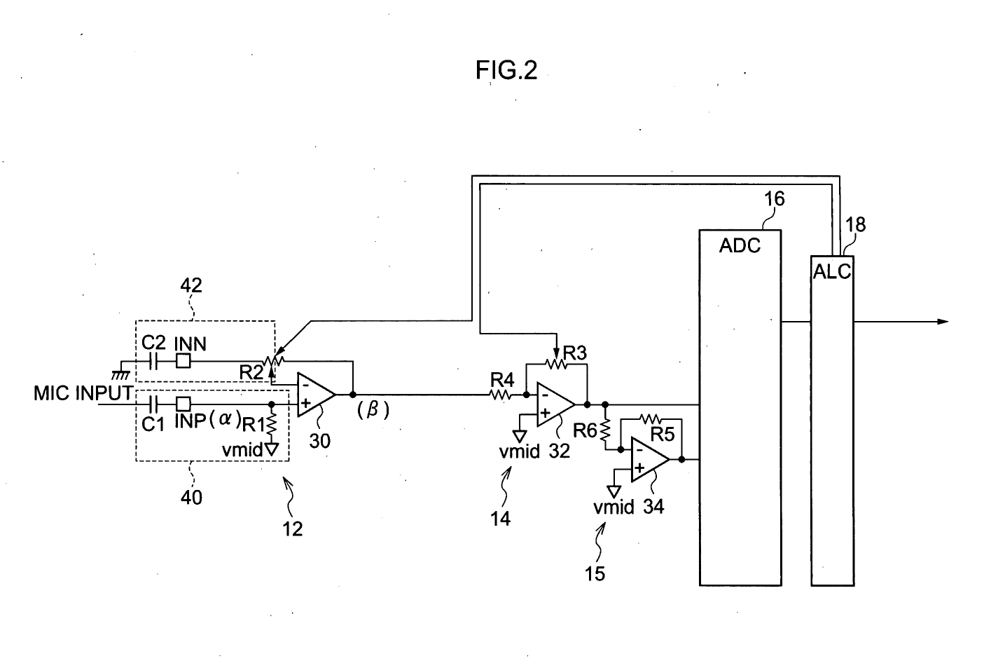

The microphone amplifier 12 has the structure of a non-inverting amplification circuit whose input impedance does not change (see FIG. 2). This is because if the structure was of an inverting amplification circuit whose input impedance changes, the input impedance would change along with effects on the output of the connected microphone. The gain of the microphone amplifier 12 is configured to be variable. In the present exemplary embodiment, the gain of the microphone amplifier 12 is set to a value according to a control signal from the ALC 18, and an analog sound signal that is input to the microphone amplifier 12 is amplified by the specified gain.

The PGA 14 has the structure of an inverting amplification circuit, and is structured with the gain thereof being variable, similarly to the microphone amplifier 12. The gain of the PGA 14 is also set to a value according to a control signal from the ALC 18, and the analog sound signal that is input to the PGA 14 is amplified by the specified gain.

The ADC 16 is a circuit that converts the analog sound signal input from the PGA 14 to a digital sound signal. In the present exemplary embodiment, as a countermeasure against earthing noise, a differential input-type ADC is used. Specifically, as illustrated in FIG. 2, an amplifier 15 is provided succeeding the PGA 14 in the present exemplary embodiment, and generates a differential signal. That is, in the present exemplary embodiment, a single-differential converter (SDC) is formed by the PGA 14 and the amplifier 15, and a differential signal is generated by this SDC and input to the ADC 16. The ADC 16 generates the digital sound signal from the differential signal and outputs the digital sound signal to the ALC 18. The ADC 16 may alternatively have a structure in which a single input-type ADC is employed and the amplifier 15 is not provided.

A sigma-delta-type (ΣΔ) ADC may be employed as the ADC 16. The sigma-delta ADC 16 outputs, for example, a digital sound signal with low bits and a high sampling rate, such as 1 bit and 128 fₛ (a sampling rate of ×128). When this type of ADC is employed, a decimation filter may be provided succeeding the ADC 16 and preceding the ALC 18. The decimation filter applies thinning processing to the digital sound signal input thereto from the ADC 16, lowering the sampling rate. Succeeding this decimation filter, a DC-cut high pass filter (HPF hereinafter) may be provided preceding the ALC 18. The HPF cuts an unneeded DC component that is produced by the digital conversion by the ADC 16.

The ALC 18 detects levels of the digital sound signal input from the preceding stage. In accordance with the detected levels, the ALC 18 controls the respective gains of the microphone amplifier 12 and the PGA 14 so as to amplify the analog sound signal input from the microphone to a pre-specified level and input the thus-amplified analog sound signal to the ADC 16. Thus, the input sound level is automatically adjusted to a constant level. However, if the level were made constant without limit, the sound would be heavily inflected and would sound wrong to the ears. Therefore, certain limits are applied, by setting a maximum gain value (a maximum value of the total gain of the microphone amplifier 12 and the PGA 14) and suchlike. With the ALC 18 being a control circuit that detects levels of the digital sound signal and outputs control signals to the microphone amplifier 12 and the PGA 14, an input digital sound signal is outputted without any signal processing being applied to the input digital sound signal.

The digital sound signal outputted from the ALC 18 may be outputted as a recording signal as is. However, a sound quality adjustment filter processing section may be provided succeeding the ALC 18 and the digital sound signal outputted after passing through this sound quality adjustment filter processing section.

For example, a sound quality adjustment filter processing section equipped with a wind noise removal high pass filter (HPF) and a notch filter may be provided. The wind noise removal HPF removes low-frequency region wind noise components input from the microphone. This filter is employed with a predetermined cut-off frequency (for example, of the order of 100 Hz to 200 Hz). After the wind noise removal, characteristic frequencies produced depending on an equipment to which the device is mounted are removed by the notch filter.

FIG. 2 is a diagram illustrating an example of a circuit diagram of the signal processing device 10 relating to the present exemplary embodiment.

The microphone amplifier 12 is a non-inverting amplification circuit, and is provided with an operational amplifier 30, a capacitor C1 and a (fixed) resistor R1. One end of the capacitor C1 is connected to the non-inverting input terminal (the + input terminal) of the operational amplifier 30, and an analog sound signal from an unillustrated microphone is input to the other end of the capacitor C1. The capacitor C1 removes direct components of the input analog sound signal. One end of the resistor R1 is connected to the non-inverting input terminal of the operational amplifier 30, and a reference voltage vmid is applied to the other end of the resistor R1. A high pass filter (hereinafter, the first HPF) 40 is formed by the capacitor C1 and the resistor R1.

The microphone amplifier 12 is provided with a resistor R2. The resistor R2 is a variable resistance provided with at least three terminals. Of the three terminals, one of the two fixed terminals at the two ends (hereinafter, the first terminal) is connected to the output terminal of the operational amplifier 30, and the other terminal (hereinafter, the third terminal) is connected to a capacitor C2, which is described below. The remaining terminal (hereinafter, the second terminal) is connected to the inverting input terminal (the − input terminal) of the operational amplifier 30.

In the present exemplary embodiment, the resistor R2 is divided in two, with one side being used as a feedback resistor for amplification. Herebelow, descriptions are given with the resistor at the one side that is used as the feedback resistor when the resistor R2 is divided in two (that is, a resistance between the first terminal and the second terminal) being referred to as resistor Rf, and the resistor at the other side (that is, a resistance between the second terminal and the third terminal) being referred to as resistor Rs. The ALC 18 controls the gain of the microphone amplifier 12 by controlling the division ratio of the resistor R2.

The microphone amplifier 12 is provided with the capacitor C2 for removing an offset voltage of the operational amplifier 30. One end of the capacitor C2 is grounded and the other end is connected to the resistor Rs (the third terminal). A high pass filter (hereinafter, the second HPF) 42 is formed by the capacitor C2 and the resistor Rs.

The analog sound signal amplified by the microphone amplifier 12 is input to the PGA 14. The PGA 14 is an inverting amplification circuit including an operational amplifier 32, a resistor R3 and a resistor R4.

The reference voltage vmid is applied to the non-inverting input terminal of the operational amplifier 32. The output terminal of the operational amplifier 32 is connected to the amplifier 15 and the ADC 16.

The resistor R3 is a variable resistance, with one end connected to the output terminal of the operational amplifier 32 and the other end connected to the inverting input terminal of the operational amplifier 32, and functions as a feedback resistor. The resistor R4 is a fixed resistance, with one end connected to the output terminal of the operational amplifier 30 of the microphone amplifier 12 and the other end connected to the inverting input terminal of the operational amplifier 32. The ALC 18 controls the gain of the PGA 14 by controlling the resistance value of the resistor R3.

The amplifier 15 provided succeeding the PGA 14 is an inverting amplification circuit, including an operational amplifier 34, a resistor R5 and a resistor R6.

The reference voltage vmid is applied to the non-inverting input terminal of the operational amplifier 34, and the output terminal of the operational amplifier 34 is connected to the ADC 16.

The resistor R5 is a fixed resistance, with one end connected to the output terminal of the operational amplifier 34 and the other end connected to the inverting input terminal of the operational amplifier 34, and functions as a feedback resistor. The resistor R6 is a fixed voltage, with one end connected to the output terminal of the operational amplifier 32 of the PGA 14 and the other end connected to the inverting input terminal of the operational amplifier 34.

As described above, the present exemplary embodiment is characterized by the gains of the microphone amplifier 12 and the PGA 14 being put under the control of the ALC 18.

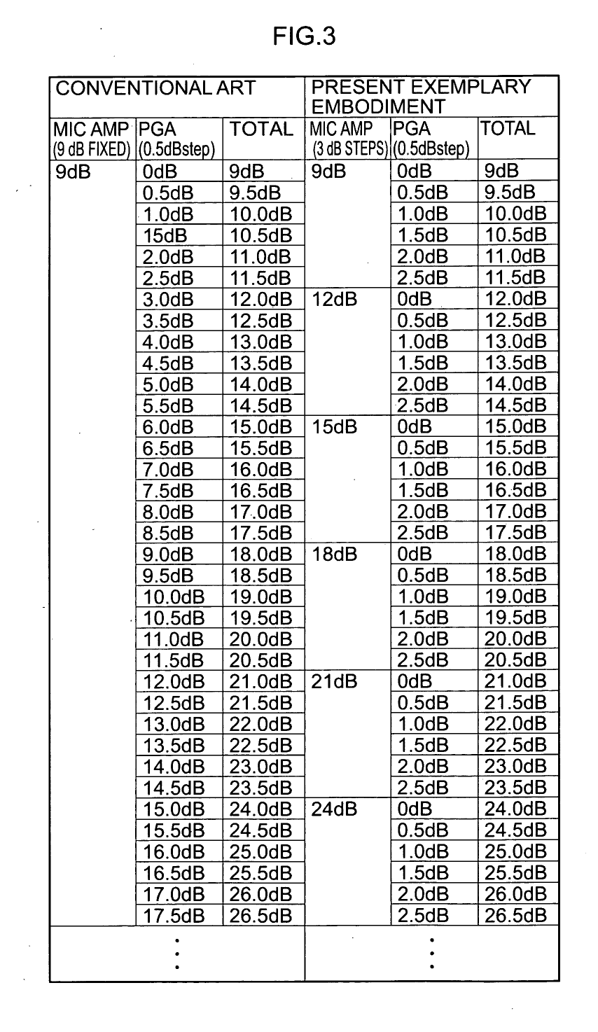

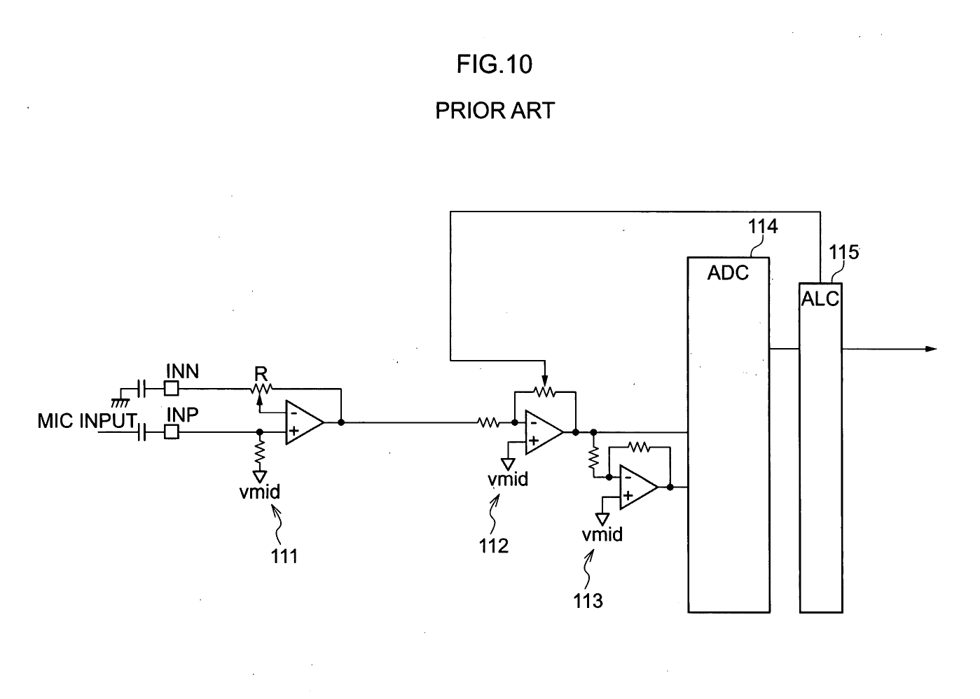

At the left side of FIG. 3, a gain assignment example is illustrated for when, as in the structure of the conventional technology illustrated in FIG. 10, the gain of the PGA 112 is variable but the gain of the microphone amplifier 111 is fixed, for a configuration in which a total gain of the gain of the microphone amplifier 111 and the gain of the PGA 112 (hereinafter referred to as the total gain) is variable in steps of 0.5 dB from a lower limit of 9 dB. If, as illustrated, the microphone amplifier 111 is configured such that the gain thereof is a fixed to 9 dB and the PGA 112 is configured with the gain thereof being variable in steps of 0.5 dB from 0 dB, the total gain may be controlled in increments of 0.5 dB from 9 dB. Because the gain of the microphone amplifier 111 is fixed, the upper limit of the range of total gain depends on the PGA 112. Therefore, if the range of gain is to be widened in order to amplify analog sound signals to a required level, the feedback resistor provided at the PGA 112 must be increased. Furthermore, if the number of steps is to be increased, more switching elements must be provided at the feedback resistor of the PGA 112.

At the right side of FIG. 3, a gain assignment example is illustrated for when, as in the structure of the present exemplary embodiment, both the gain of the microphone amplifier 12 and the gain of the PGA 14 are variable, for a configuration in which the total gain is variable in steps of 0.5 dB from a lower limit of 9 dB. If, as illustrated, the microphone amplifier 12 is configured with the gain thereof being variable in steps of 3 dB from 9 dB and the PGA 14 is configured with the gain thereof being variable in steps of 0.5 dB from 0 dB to 2.5 dB, the total gain may be controlled in increments of 0.5 dB from 9 dB.

Now, if analog sound signals are to be amplified variably in a range of total gain from 9 dB to 20.5 dB in increments of 0.5 dB, with the structure of the conventional technology, the number of steps in the gain of the PGA 112 must be 24 and the range of the gain of the PGA 112 must be from 0 dB to 11.5 dB, which is a wide range of gain. Correspondingly, the feedback resistor constituting the PGA 112 is large, thermal noise increases, and the size of the circuit increases. In contrast, with the structure of the present exemplary embodiment, the number of steps in gain of the microphone amplifier 12 for the range from 9 dB to 18 dB is 4, and the number of steps in gain of the PGA 14 for the range from 0 dB to 2.5 dB is 6. Thus, because the numbers of steps are kept down, the number of switching elements may be smaller, and the size of the circuit is smaller. Moreover, considering only the PGA 14, the range of the gain may be greatly reduced, and the size of the resistor R2 that is used (the resistor Rf) may be smaller.

When the gain of the microphone amplifier 12 is made variable in this manner, if the range of the total gain is to be further widened, the range of gain of the microphone amplifier 12 is increased. In contrast with widening the range with the PGA 112 alone as in the structure of the related art, since the gain is divided into two components, the respective ranges of gain of the microphone amplifier 12 and the PGA 14 may be narrower. Furthermore, for example, if, as another gain assignment example, the range of the PGA 14 is made wider than the example shown at the right side of FIG. 3, an increase in the range of the microphone amplifier 12 may be relatively restrained, and when the range of the total gain widens, the ranges of gain of each of the microphone amplifier 12 and the PGA 14 may be smaller on average.

Thus, because the total gain is distributed between the gain of the microphone amplifier 12 and the gain of the PGA 14, an analog sound signal may be amplified to a required level using smaller resistors than if only the gain of the PGA 14 were variable, thermal noise may be suppressed, and the size of the circuit may be reduced.

Although not illustrated in the above-mentioned FIG. 1 and FIG. 2 or in FIG. 10 illustrating the conventional structure, it is common for the control of gain to be implemented by detecting zero-crossing points of a sound signal with a zero-crossing detector.

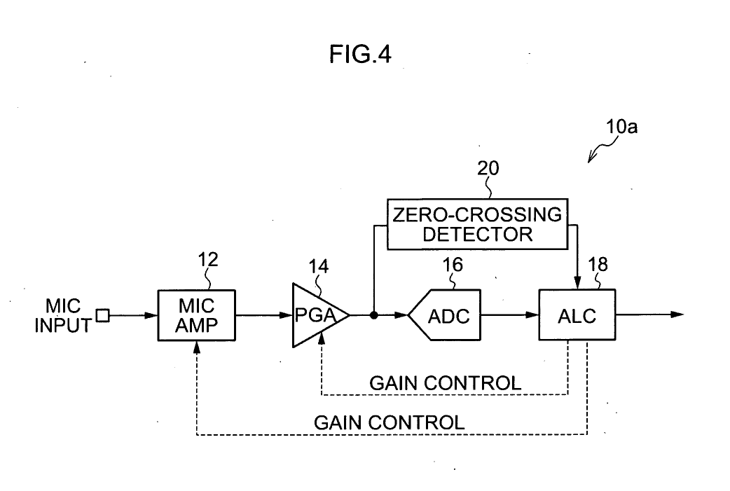

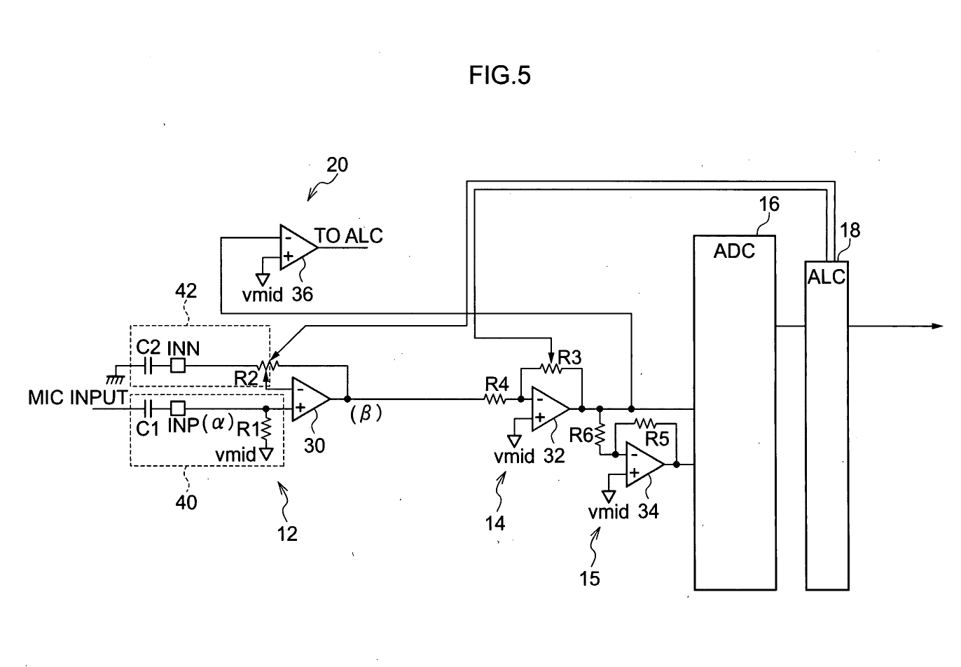

FIG. 4 is a diagram illustrating a structural example when a zero-crossing detector 20 is provided in the signal processing device 10 illustrated in FIG. 1. FIG. 5 is a diagram illustrating an example of a circuit diagram corresponding to the structure of FIG. 4. Structural elements for which the reference numerals shown in FIG. 4 and the reference numerals shown in FIG. 1 are the same signify structural elements that have the same respective functions, so descriptions thereof are not given. In addition, structural elements for which the reference numerals shown in FIG. 5 and the reference numerals shown in FIG. 2 are the same signify structural elements that have the same respective functions, so descriptions thereof are not given.

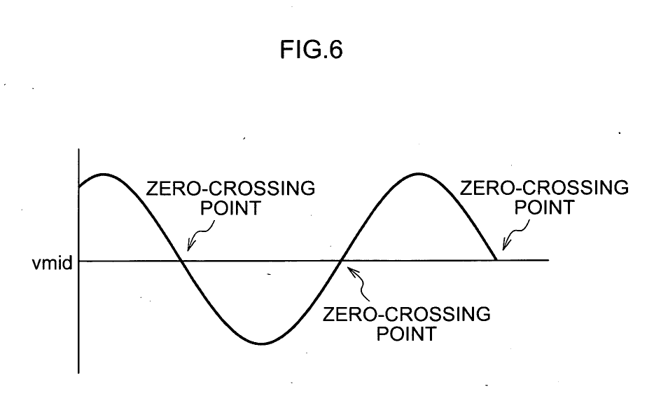

The zero-crossing detector 20 detects a timing (a zero-crossing point) at which the analog sound signal outputted from the PGA 14 is at signal ground (an amplitude zero level, which is the reference voltage vmid in the present exemplary embodiment), and reports the timing to the ALC 18 (see FIG. 6). The ALC 18 controls (switches) the gain at times at which the detection of a zero-crossing point is reported. As illustrated in FIG. 5, the zero-crossing detector 20 is structured to include a comparator 36. An inverting input terminal of the comparator 36 is connected to the output terminal of the PGA 14. The reference voltage vmid is applied to the non-inverting input terminal of the comparator 36. The output terminal of the comparator 36 is connected to the ALC 18. The comparator 36 compares the analog sound signal outputted from the PGA 14 with the reference voltage vmid, and detects zero-crossing points (i.e., the output thereof inverts at times at which the input analog sound signal is at the reference voltage vmid).

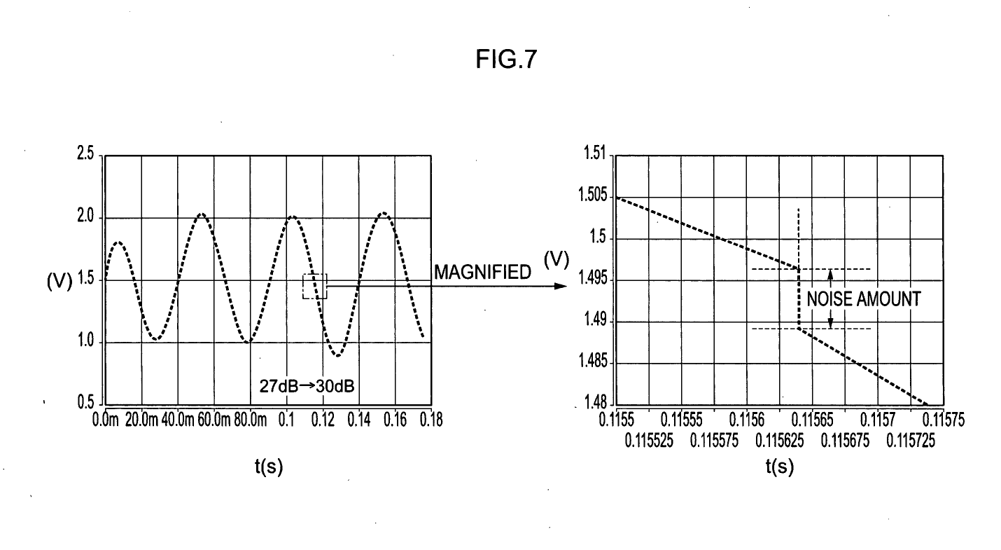

FIG. 7 is a diagram illustrating an example of popcorn noise that is caused by gain switching when the gain is switched from 27 dB to 30 dB. If the gain is switched at a zero-crossing point, continuity is preserved to a certain extent, and popcorn noise that is caused by non-continuous operation at the time of the gain switching may be kept to a minimum. Herebelow, the operation of controlling the gain at the zero-crossing points is abbreviated to the term “zero-crossing operation”.

In the related art, because the gain of the microphone amplifier serving as the non-inverting amplification circuit is fixed, the gain of the microphone amplifier is not switched with zero-crossing points being detected. In contrast, when the zero-crossing operation is performed with the structure in which the gain of the microphone amplifier 12 is variable as in the present exemplary embodiment, the following problem may arise.

Because the microphone amplifier 12 is constituted by a non-inverting amplification circuit, a phase delay may be produced between the input (α in FIG. 5) and output ((β in FIG. 5) of the operational amplifier 30, depending on the capacitor C2 and the resistor Rs. For example, with a gain of 30 dB, a phase delay of 50° to 60° is produced at the output side for a frequency of 20 Hz. In this case, when zero-crossing operations are attempted while processing a sound signal with a frequency of 20 Hz, the input α is advanced in phase by 50° to 60° relative to the zero-crossing points (the 0° and 180° positions). Therefore, correct zero-crossing operations are not performed. As a result, substantial popcorn noise is produced.

Although not illustrated, the phase difference between the input α and output of the operational amplifier 30 is larger for frequencies of the input analog sound signal that are closer to a cut-off frequency fc2 of the second HPF 42. The larger the phase difference (herein, the closer to a phase difference of 90° or 270° at which the amplitude is at a peak), the larger an amount of noise at a zero-crossing time.

Accordingly, in order to moderate the noise amounts, adjustment of the circuit constant is performed. Specifically, the frequencies of an input analog sound signal are limited to frequencies higher than the cut-off frequency fc2. Therefore, frequency components in which a phase delay occurs may be cut off, and the noise amounts may be kept small. As described above, in the conventional art, the magnitude of the gain of the microphone amplifier is fixed and therefore there is no need to perform an adjustment of the circuit constant. However, if the zero-crossing operations are performed with the structure in which the gain of the microphone amplifier is variable as in the present exemplary embodiment, this adjustment of the circuit constant is useful.

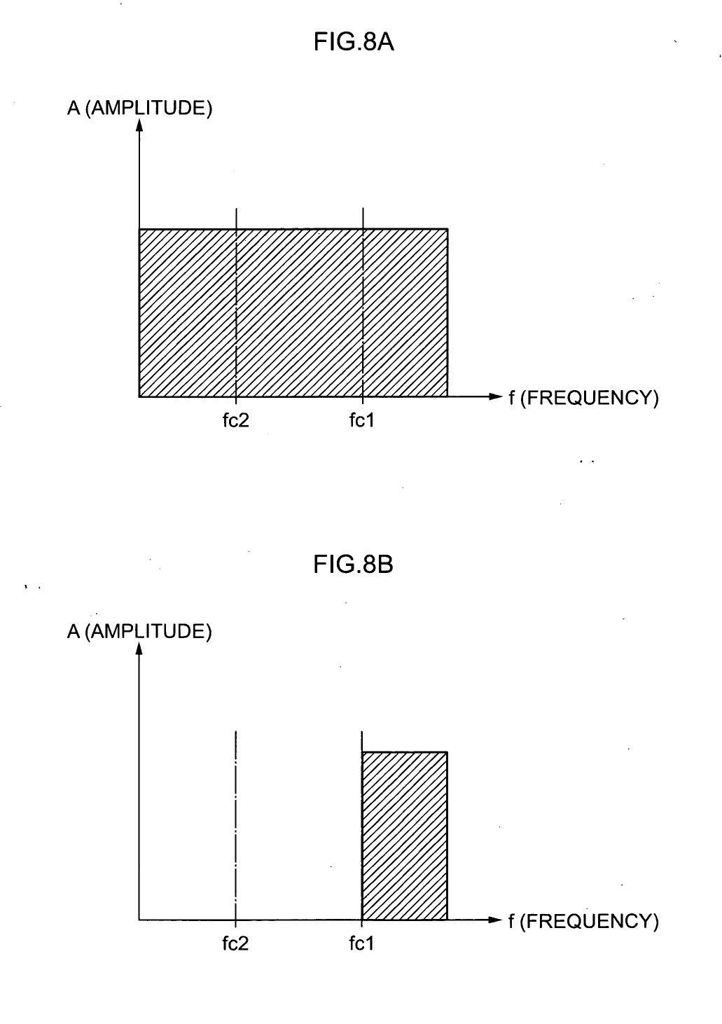

FIG. 8A and FIG. 8B are explanatory diagrams schematically describing relationships between a cut-off frequency fc1 of the first HPF 40 and the cut-off frequency fc2. FIG. 8A schematically illustrates the input analog sound signal (shaded in the drawing). Frequency components of this analog sound signal that are close to the cut-off frequency fc2 affect the production of noise. Therefore, as illustrated in FIG. 8B, the cut-off frequency fc1 is set higher than the cut-off frequency fc2 so as to cut off frequencies close to fc2, and frequency components lower than the cut-off frequency fc1 are cut off.

Thus, because the cut-off frequency fc1 of the first HPF 40 is set higher than the cut-off frequency fc2 of the second HPF 42, components close to the cut-off frequency fc2 are cut off. The larger the difference between the cut-off frequency fc1 and the cut-off frequency fc2, the more components close to the cut-off frequency fc2 may be cut off. Consequently, noise at zero-crossing times may be moderated.

If the capacitance value of the capacitor C1 is c1 and the resistance value of the resistor R1 is r1, the cut-off frequency fc1 is expressed by the following equation.

fc1=1/(2π×c1×r1)

If the capacitance value of the capacitor C2 is c2 and the resistance value of the resistor Rs is rs, the cut-off frequency fc2 is expressed by the following equation.

fc2=1/(2π×c2×rs)

Therefore, by adjusting the settings of the capacitance value c1 of the capacitor C1, the resistance value r1 of the resistor R1, the capacitance value c2 of the capacitor C2 and the resistance value rs of the resistor Rs, the cut-off frequency fc1 is adjusted to be larger than the cut-off frequency fc2. In the present exemplary embodiment, the resistance value rs of the resistor Rs is set by the division ratio with the resistor Rf being controlled by the ALC 18. Therefore, in the present exemplary embodiment, a limit on the range of variation of the resistance value rs of the resistor Rs (or the division ratio) is set such that fc1 is always larger than fc2 in respect of the other circuit constant, and this limit is set at the ALC 18.

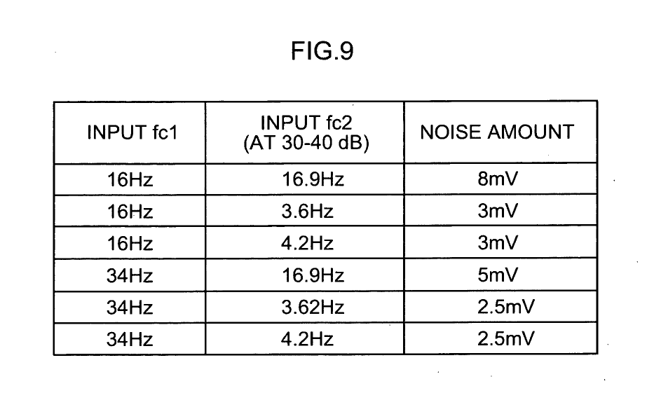

FIG. 9 illustrates examples of settings of the cut-off frequencies fc1 and fc2 and results of simulation of noise amounts. As illustrated in FIG. 9, the larger the difference between the cut-off frequency fc1 and the cut-off frequency fc2, the smaller the amount of noise. Obviously, these are examples and the cut-off frequency fc1 and cut-off frequency fc2 are not to be limited to these.

The present invention is not to be limited by the exemplary embodiment described above; numerous design modifications may be applied within the technical scope of the inventions recited in the claims.

For example, in the exemplary embodiment described above, an example is described in which the first resistor R2 is divided in two and used as the feedback resistor Rf and the resistor Rs, and the ALC 18 controls the gain of the microphone amplifier 12 by controlling this division ratio. However, this is not to be limiting. For example, the feedback resistor Rf and the resistor Rs may be separately provided. More specifically, a resistor Ra corresponding to the feedback resistor Rf may be provided between the output terminal and inverting input terminal of the operational amplifier 30 of the microphone amplifier 12, and a resistor Rb corresponding to the resistor Rs may be provided between the inverting input terminal and the capacitor C2. Here, the resistor Ra is structured as a variable resistance. The resistant Rb may be a fixed resistance. The ALC 18 controls the gain of the microphone amplifier 12 by controlling the resistance value of the resistor Ra.

If the two resistors Ra and Rb are provided at the inverting input side in this manner, the aforementioned second HPF 42 is constituted by the capacitor C2 and the resistor Rb. Therefore, if the capacitance value of the capacitor C2 is c2 and the resistance value of the resistor Rb is rb, the cut-off frequency fc2 of the second HPF 42 is expressed by the following equation.

fc2=1/(2π×c2×rb)

Accordingly, the capacitance value c1 of the capacitor C1, the resistance value r1 of the resistor R1, the capacitance value c2 of the capacitor C2 and the resistance value rb of the resistor Rb are set in advance such that fc1 is larger than fc2.

The foregoing description of the exemplary embodiment of the present invention has been provided for the purpose of illustration and description. It is not intended to be exhaustive or to limit the invention to the precise form disclosed herein. Obviously, many modifications and variations will be apparent to a practitioner skilled in the art. The exemplary embodiments were chosen and described in order to explain the principles of the invention and its practical applications, thereby enabling others skilled in the art to understand the invention according to various embodiments and with various modifications as are suited to the particular use contemplated. It is intended that the scope of the invention be defined by the following claims and their equivalents.

What is claimed is:

1. A signal processing device comprising:
a non-inverting amplifier that amplifies a level of an analog sound signal input from outside with a first gain whose value is variable;
an inverting amplifier that amplifies a level of the analog sound signal amplified by the non-inverting amplifier with a second gain whose value is variable;
a converter that converts the analog sound signal amplified by the inverting amplifier to a digital sound signal; and
a controller that detects a level of the digital sound signal converted by the converter and, in accordance with the detected level of the digital sound signal converted by the converter, controls the first gain and the second gain such that a level of the analog sound signal input to the converter is at a pre-specified level.

2. The signal processing device according to claim 1, further comprising:
a zero-crossing detector that detects zero-crossing points of the analog sound signal amplified by the inverting amplifier,
wherein the controller controls the first gain and the second gain when a zero-crossing point is detected by the zero-crossing detector.

3. The signal processing device according to claim 1, further comprising:
a first high pass filter connected to a non-inverting input terminal of the non-inverting amplifier; and
a second high pass filter connected to an inverting input terminal of the non-inverting amplifier,
wherein a cut-off frequency of the first high pass filter is higher than a cut-off frequency of the second high pass filter.

4. A signal processing device comprising:
a non-inverting amplification circuit that amplifies an input analog sound signal with a first gain whose value is variable, the non-inverting amplification circuit including
a first operational amplifier,
a first capacitor, one end of which is connected to a non-inverting input terminal of the first operational amplifier, the analog sound signal being input through the other end of the first capacitor and the first capacitor removing a DC component of the analog sound signal,
a first resistor, one end of which is connected to the non-inverting input terminal of the first operational amplifier, a reference voltage being applied to the other end of the first resistor,
a second resistor, one end of which is connected to an output terminal of the first operational amplifier and the other end of which is connected to an inverting input terminal of the first operational amplifier, the second resistor functioning as a feedback resistor,
a second capacitor, one end of which is grounded, the second capacitor being for removing an offset voltage of the first operational amplifier, and
a third resistor, one end of which is connected to the other end of the second capacitor and the other end of which is connected to the inverting input terminal of the first operational amplifier;
an inverting amplification circuit that amplifies the analog sound signal amplified by the non-inverting amplification circuit with a second gain whose value is variable, the inverting amplification circuit including
a second operational amplifier, the reference voltage being applied to a non-inverting input terminal thereof,
a fourth resistor, one end of which is connected to an output terminal of the second operational amplifier and the other end of which is connected to an inverting input terminal of the second operational amplifier, the fourth resistor functioning as a feedback resistor, and
a fifth resistor, one end of which is connected to the output terminal of the first operational amplifier and the other end of which is connected to the inverting input terminal of the second operational amplifier;
a conversion circuit that converts the analog sound signal amplified by the inverting amplification circuit to a digital sound signal; and
a control circuit that detects a level of the digital sound signal converted by the conversion circuit and, in accordance with the detected level of the digital sound signal converted by the conversion circuit, controls the first gain and the second gain such that a level of the analog sound signal input to the conversion circuit is at a pre-specified level.

5. The signal processing device according to claim 4, further comprising a comparator that is connected to the control circuit and that compares the analog sound signal amplified by the inverting amplification circuit with the reference voltage and detects zero-crossing points,
wherein the control circuit controls the first gain and the second gain when a zero-crossing point is detected by the comparator, and
a cut-off frequency of a first high pass filter that is formed by the first capacitor and the first resistor is higher than a cut-off frequency of a second high pass filter that is formed by the second capacitor and the third resistor.

6. A signal processing method comprising:
primarily amplifying a level of an analog sound signal input from outside, with a first gain whose value is variable;
secondarily amplifying a level of the analog sound signal which has been primarily amplified, with a second gain whose value is variable;
converting the analog sound signal which has been secondarily amplified to a digital sound signal;
detecting a level of the converted digital sound signal; and,
in accordance with the detected level of the converted digital sound signal, controlling the first gain and the second gain such that a level of the analog sound signal to be converted is at a pre-specified level.

7. The signal processing method according to claim 6 further comprising:
controlling the first gain and the second gain when a zero-crossing point of the secondarily amplified analog sound signal is detected.

8. The signal processing method according to claim 6 further comprising:
providing a first high pass filter connected to a non-inverting input terminal of a non-inverting amplifier which performs the primary amplifying and a second high pass filter connected to an inverting input terminal of the non-inverting amplifier, and setting a cut-off frequency of the first high pass filter higher than a cut-off frequency of the second high pass filter.
